(19) United States
(12) Patent Application Publication
(10) Pub. No.: US 2013/0119529 A1
(43) Pub. Date: May 16, 2013

(54) SEMICONDUCTOR DEVICE HAVING LID STRUCTURE AND METHOD OF MAKING SAME

(71) Applicants: Wen-Yi LIN, New Taipei City (TW); Po-Yao LIN, Zhudong Township (TW)

(72) Inventors: Wen-Yi LIN, New Taipei City (TW); Po-Yao LIN, Zhudong Township (TW)

(73) Assignee: TAIWAN SEMICONDUCTOR MANUFACTURING COMPANY, LTD., Hsinchu (TW)

(21) Appl. No.: 13/296,649

(22) Filed: Nov. 15, 2011

(51) Int. Cl. H01L 23/04; H01L 21/58; H01L 23/34

(52) U.S. Cl. 257/704; 257/706; 438/118; 257/E23.181; 257/E23.08; 257/E21.505

(57) ABSTRACT

A semiconductor device includes a substrate, a first die attached to the substrate, and a lid coupled to the substrate. The lid defines a cavity for engaging the first die, and the lid has a die enclosure barrier having ends extending downwardly into the cavity. The ends of the die enclosure barrier are attached to the substrate and a thermal interface material is disposed between the first die and the lid, thermally connecting the first die to the lid.

### FIELD

The disclosure relates generally to semiconductor devices and more particularly to semiconductor packages of the semiconductor devices.

### BACKGROUND

Current semiconductor devices typically include a die, a substrate, a heat spreader, a thermal interface material (TIM) for coupling the die to the heat spreader, one or more metallization layers, input/output (I/O) pins or balls, and optionally a heat sink. The die contains the active circuitry of the device and is typically mounted on the substrate or in a cavity within the substrate. As the active surface of the die faces down, such semiconductor devices are often referred to as “flip chip” packages.

In modern semiconductor packages, the continued push for higher performance and smaller size leads to higher operating frequencies and increased package density (more transistors per unit area). In operation the circuitry on such a die consumes an appreciable amount of electrical energy and this energy invariably creates heat. This is especially true if the die is a high power consumption chip such as a central processing unit (CPU). Conventional TIMs that couple the die to the heat spreader function to dissipate heat generated in the die to the ambient. However, along with heat the die may also operate in a high moisture operating environment. This high moisture content may enter the semiconductor package and adversely affect the performance of the die. With moisture incursion and increased operating temperatures, the ability of the TIM to dissipate heat may be reduced subjecting the die to reduced performance and/or failure.

### BRIEF DESCRIPTION OF DRAWINGS

The features, aspects, and advantages of the disclosure will become more fully apparent from the following detailed description, appended claims, and accompanying drawings in which:

FIG. 1 is a cross-sectional view of a semiconductor device according to an exemplary embodiment of the present disclosure.

FIG. 2 is a top view of the semiconductor device depicted in FIG. 1.

FIG. 3 is a flowchart of a method of fabricating a semiconductor device according to various aspects of the present disclosure.

### DETAILED DESCRIPTION

In the following description, numerous specific details are set forth to provide a thorough understanding of embodiments of the present disclosure. However, one having an ordinary skill in the art will recognize that embodiments of the disclosure can be practiced without these specific details. In some instances, well-known structures and processes are not described in detail to avoid unnecessarily obscuring embodiments of the present disclosure.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

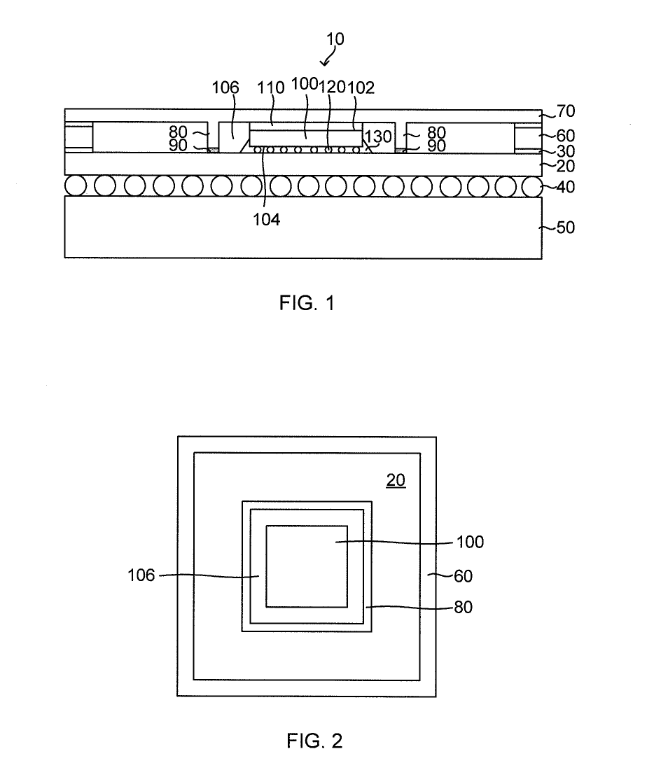

FIG. 1 depicts a semiconductor device 10 according to an exemplary embodiment of the present disclosure. A top view of the semiconductor device 10 is depicted in FIG. 2. As illustrated, semiconductor device 10 includes, among other components, a first substrate 20, a die 100, and a lid 70. As will become apparent, lid 70 acts as a heat spreader.

Semiconductor device 10 includes die 100 having an upper surface 102 and a lower surface 104 opposite the upper surface 102. Die 100 may, for example, embody a general purpose processor, graphics processor, or the like having one or more processing cores. Die 100 may be a processor readable memory, in the form of static or dynamic random access memory (DRAM, SDRAM or the like), readable by the processor embodied in another die. Of course, die 100 could embody other electronic devices, such as application specific integrated circuits, microcontroller, field programmable gate arrays, or the like.

A first set of package pins 120 is connected to contact pads (not shown) on the lower surface 104 of die 100. The first set of package pins 120 may be solder bumps or any other known electrical package interconnect. In operation, power and electrical signals are applied to die 100 by way of package pins 120. In the depicted embodiment, die 100 is secured to the first substrate 20 underlying die 100. In some embodiments, die 100 is embedded in first substrate 20. In some embodiments, semiconductor device 10 includes one or more dies mounted atop die 100. In still some embodiments, semiconductor device 10 includes one or more dies mounted to the first substrate 20 alongside the die 100. The one or more dies may be electrically interconnected to each other and/or to die 100 by way of microvias (not shown) formed therein and/or in die 100.

First set of package pins 120 are attached to contact pads (not shown) on an upper surface of first substrate 20. An underfill 130 may be filled between die 100 and first substrate 20 to stiffen the semiconductor device 10 and protect die 100 from flexural damage. A second set of package pins 40 may be secured to contact pads (not shown) on a lower surface of first substrate 20. Second set of package pins 40 may be solder balls or any other known electrical package interconnect. Second set of package pins 40 may also be secured to contact pads (not shown) on a second substrate 50. The second substrate 50 may be a printed wire board (also sometimes called a printed circuit board) or may be a multilayer module known to those skilled in the art.

Lid 70 acts as a cap for semiconductor device 10 and as a heat spreader. In one embodiment, lid 70 is mounted over die 100 to dissipate heat generated by die 100 and other dies and to counter-balance the forces exerted by the thermal expansion mismatches between at least the die 100 and the first substrate 20. In one embodiment, lid 70 is monocoque structure that is attached to first substrate 20 by means of adhesives, epoxy, glue or the like (not shown) around the edges of lid 70. In the embodiment depicted in FIG. 1, stiffener 60 is mounted between first substrate 20 and lid 70 by means of first adhesives 30. First adhesives 30 may include, for example epoxy, glue or the like.

According to one embodiment, lid 70 is generally dome shaped having a flat top. It is to be appreciated by those skilled in the art that lid 70 need not be flat. In some embodiments, lid 70 can have any suitable shapes such as flat, concave, convex or the like tops. Lid 70 has a die enclosure barrier 80 having one or more edges or ends that extend downward from the top of lid 70 to the first substrate 20 and are attached thereto. Numerous variations of shapes and sizes of the die enclosure barrier 80 will become apparent to those skilled in the art without departing from the scope of the claims attended herein.

The enclosure barrier 80 may be attached to the first substrate 20 by means of a second adhesive 90 that connects the edges or ends of the die enclosure barrier 80 to the first substrate 20. Second adhesive 90 may include, for example epoxy, glue, Thermoplastic Polyurethane (TPU) or the like and may, according to one embodiment be a thin film. According to one embodiment, the second adhesive 90 may be a bead of epoxy and applied by a glue seam technique and later cured to affix the lid to the first substrate 20 by techniques known to those skilled in the art. The top of lid 70 and the die enclosure barrier 80 define a cavity 106. Cavity 106 covers a portion of first substrate 20 and receives die 100 or a plurality of dies. In other words, the die enclosure barrier 80 surrounds the die or dies it is intended to receive.

Lid 70 and/or die enclosure barrier 80 may be formed of a molded heat conducting material, such as a metal including for example aluminum, steel or the like. Lid 70 (including die enclosure barrier 80) may be integrally formed by, for example, stamping, molding or using other fabrication techniques. Lid 70 (including die enclosure barrier 80) could alternatively be formed from another heat conducting material, such as a suitable ceramic, alloy, or the like. In some embodiments, the die enclosure barrier 80 is made of substantially the same material as the lid 70. In other embodiments, the die enclosure barrier 80 is made of a different material than the lid 70.

In one embodiment of the present disclosure, the region between lid 70 and die 100 includes a thermal interface material (TIM) 110. The TIM 110 thermally connects die 100 to the bottom surface of the lid 70 for transferring heat generated by die 100 to lid 70. TIM 110 may be applied to die 100 by techniques known to those skilled in the art. In the depicted embodiment of FIG. 1, TIM 110 is a viscous, semi-viscous, liquid or similar thermal interface material. Suitable materials for TIM 110 may be inorganic gels; organic gels; grease; or the like. Suitable gels may be available from SHIN-ETSU CHEMICALS of Tokyo, Japan, under for example, part number SHIN-ETSU MICROS I x23-7809.

In some embodiments, an aspect of the present disclosure has the die enclosure barrier 80 surrounding the die or dies it is intended to receive. This is advantageous in that by surrounding the die, one or more embodiments of the semiconductor device 10 can reduce moisture incursion when the device operates in a high temperature and high moisture operating environment. By blocking or reducing the moisture that enters into cavity 106, TIM 110 will be better able to perform its function which is to dissipate heat so that die 100 may avoid the deleterious effects of high heat and/or high moisture. As an added benefit of the blocked or reduced moisture in the device in some embodiments, the substrate warpage is lowered thereby enhancing the devices corner and edge bump integrity.

In some embodiments of the present disclosure, the semiconductor device 10 also includes a molding compound (not shown) that is disposed in the cavity 106. The molding compound encapsulates at least the die 100, portions of first substrate 20, and the TIM 110 to at least enhance the structural integrity of the device and may assist in dissipating the heat.

Ultimately heat is transferred to the atmosphere by conduction or convection, as lid 70 and first substrate 20 are in thermal communication with the environment. An external fan or other cooling device (not shown) may aid in transporting dissipated heat from device 10.

As will now be appreciated, embodiments disclosed herein could easily be modified to include more than one die. For example, two or more dies could be stacked. Lid 70 and/or die enclosure barrier 80 could be adapted accordingly, having ends of different lengths, sizes, and/or shapes Likewise, first substrate 20 could have formed thereon multiple stacked dies spaced apart from each other on first substrate 20.

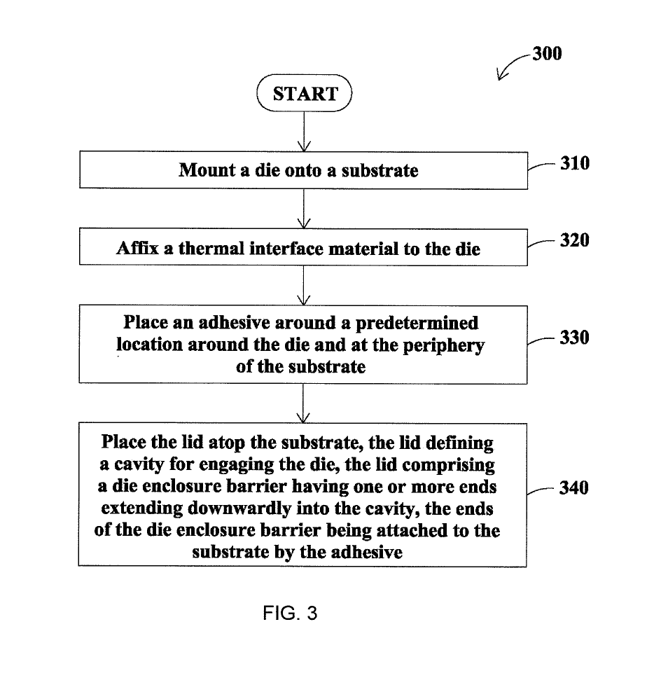

Illustrated in FIG. 3 is a flowchart of a method 300 of fabricating a semiconductor device according to various aspects of the present disclosure. Referring to FIG. 3, the method includes block 310, in which a die is mounted onto a substrate. Then the process moves on to block 320, in which a thermal interface material (TIM) is affixed to the die. Then the process moves on to block 330, in which an adhesive is placed around a predetermined location around the die and at the periphery of the substrate. The adhesive is arranged to receive a lid. Then the process moves on to block 340, in which the lid is placed atop the substrate. The lid defines a cavity for engaging the die. The lid comprises a die enclosure barrier having one or more ends extending downwardly into the cavity, the ends of the die enclosure barrier being attached to the substrate by the adhesive.

It is understood that additional processes may be performed before, during, or after the blocks 310-340 shown in FIG. 3 to complete the fabrication of the semiconductor device, but these additional processes are not discussed herein in detail for the sake of simplicity.

The present disclosure has described various exemplary embodiments. According to one embodiment, a semiconductor device comprises a substrate; a first die attached to the substrate; a lid coupled to the substrate, the lid defining a cavity for engaging the first die, the lid comprising a die enclosure barrier having ends extending downwardly into the cavity, the ends of the die enclosure barrier attached to the substrate; and a thermal interface material between the first die and the lid, thermally connecting the first die to the lid.

According to another embodiment, a semiconductor device comprises a substrate; a die attached to the substrate; a heat spreader coupled to the substrate, the heat spreader defining a cavity and comprising a die enclosure barrier having ends extending downwardly into the cavity, the ends of the die enclosure barrier attached to the substrate and surrounding the die; and a thermal interface material between the die and the heat spreader, thermally connecting the die to the heat spreader.

According to yet another embodiment of the present disclosure, a method of forming a semiconductor device comprises mounting a die onto a substrate; affixing a thermal interface material to the die; placing an adhesive around a predetermined location around the die and at the periphery of the substrate, the adhesive for receiving a lid; placing the lid atop the substrate, the lid defining a cavity for engaging the first die, the lid comprising a die enclosure barrier having ends extending downwardly into the cavity, the ends of the die enclosure barrier being attached to the substrate by the adhesive; and curing the adhesive to affix the lid to the substrate.

In the preceding detailed description, specific exemplary embodiments have been described. It will, however, be apparent to a person of ordinary skill in the art that various modifications, structures, processes, and changes may be made thereto without departing from the broader spirit and scope of the present disclosure. The specification and drawings are, accordingly, to be regarded as illustrative and not restrictive. It is understood that embodiments of the present disclosure are capable of using various other combinations and environments and are capable of changes or modifications within the scope of the claims.

1. A semiconductor device comprising:
a substrate;
a first die attached to the substrate;
a lid coupled to the substrate, the lid defining a cavity for engaging the first die, the lid comprising a die enclosure barrier having one or more ends extending downwardly into the cavity, the ends of the die enclosure barrier attached to the substrate; and
a thermal interface material between the first die and the lid, the thermal interface material thermally connecting the first die to the lid.

2. The semiconductor device of claim 1, wherein the die enclosure barrier is made of substantially the same material as the lid.

3. The semiconductor device of claim 1, wherein the die enclosure barrier is made of a different material than the lid.

4. The semiconductor device of claim 1, wherein the ends of the die enclosure barrier surrounds the first die.

5. The semiconductor device of claim 1, wherein the ends of the die enclosure barrier are attached to the substrate by an adhesive.

6. The semiconductor device of claim 5, wherein the adhesive is a thin film.

7. The semiconductor device of claim 5, wherein the adhesive comprises Thermoplastic Polyurethane (TPU).

8. The semiconductor device of claim 1, further comprising an underfill material formed in a gap between the first die and the substrate.

9. The semiconductor device of claim 1, wherein the lid further comprises stiffeners for coupling to the substrate.

10. The semiconductor device of claim 1, further comprising a molding compound filling the cavity and being in thermal communication with at least the first die and the substrate.

11. The semiconductor device of claim 1, further comprising a second die mounted atop the first die.

12. The semiconductor device of claim 1, further comprising a second die mounted to the substrate.

13. A semiconductor device comprising:
a substrate;
a die attached to the substrate;
a heat spreader coupled to the substrate, the heat spreader defining a cavity and comprising a die enclosure barrier having one or more ends extending downwardly into the cavity, the ends of the die enclosure barrier attached to the substrate and surrounding the die; and
a thermal interface material between the die and the heat spreader, thermally connecting the die to the heat spreader.

14. The semiconductor device of claim 13, wherein the ends of the die enclosure barrier are attached to the substrate by an adhesive.

15. The semiconductor device of claim 13, wherein the adhesive comprises Thermoplastic Polyurethane (TPU).

16. The semiconductor device of claim 13, wherein the heat spreader comprises stiffeners for coupling to the substrate.

17-21. (canceled)

22. A semiconductor device comprising:
a substrate;
one or more dies mounted to an upper surface of the substrate;
an enclosure barrier mounted to the upper surface of the substrate and surrounding the one or more dies;
a lid over the enclosure barrier and the one or more dies, an edge portion of the lid being mounted to the upper surface of the substrate, and the enclosure barrier being attached to the lid between the edge portion and the one or more dies; and
a thermal interface material between at least one of the one or more dies and the lid.

23. The semiconductor device of claim 22, wherein the enclosure barrier is made of substantially the same material as the lid.

24. The semiconductor device of claim 23, wherein the enclosure barrier and the lid are integrally formed.

25. The semiconductor device of claim 22, wherein the enclosure barrier is made of a different material than the lid.

26. The semiconductor device of claim 22, wherein an end of the enclosure barrier is mounted to the upper surface of the substrate by an adhesive.
